(19) United States
(12) Patent Application Publication
(10) Pub. No.: US 2024/0096744 A1
(43) Pub. Date: Mar. 21, 2024

(54) SEMICONDUCTOR DEVICE AND INVERTER UNIT

(71) Applicant: Mitsubishi Electric Corporation, Tokyo (JP)

(72) Inventors: Nobuyoshi KIMOTO, Fukuoka (JP); Mitsunori AIKO, Tokyo (JP)

(73) Assignee: Mitsubishi Electric Corporation, Tokyo (JP)

(21) Appl. No.: 18/551,569

(22) PCT Filed: Aug. 10, 2021
(86) PCT No.: PCT/JP2021/029563

§ 371 Date: Sep. 20, 2023

(51) Int. Cl. H01L 23/433; H01L 21/56; H01L 23/31; H01L 23/495

(52) U.S. Cl. CPC H01L 23/4334; H01L 21/565; H01L 23/3121; H01L 23/49562; H01L 24/48

(57) ABSTRACT

A semiconductor chip (2,3) is mounted on the heat spreader (1). A frame (4) is bonded to an upper surface of the semiconductor chip (2,3). Mold resin (9) seals the heat spreader (1), the semiconductor chip (2,3) and the frame (4) and has a recess (10) provided on an upper surface of the mold resin (9). A heat dissipation plate (12) is externally attached to the recess (10) via a thermally conductive material (11) having thermal conductivity higher than that of the mold resin (9). The heat dissipation plate (12) is insulated from the semiconductor chip (2,3) and the frame (4) by the mold resin (9). The heat dissipation plate (12) is a flat plate having an upper surface and a lower surface which are opposite to each other and flat.

### FIELD

The present disclosure relates to a semiconductor device and an inverter unit.

### BACKGROUND

There has been proposed, as a conventional semiconductor device having a double-sided cooling structure, one in which a heat dissipation plate is exposed from both surfaces of a mold (see, e.g., Patent Literature 1).

### CITATION LIST

### Patent Literature

[PTL 1] JP 2012-4358 A

### SUMMARY OF THE INVENTION

### Problems to be Solved by the Invention

In a conventional device, a heat dissipation plate on both surfaces of a mold has been connected to a semiconductor chip or the like in the device. Therefore, when the device is incorporated into an inverter unit, the device has been stacked on a heat sink by externally providing an insulating plate and grease on both the surfaces of the mold to have an insulating property of the heat dissipation plate. Accordingly, there has been a problem that the number of components and the number of assembly man-hours are large, resulting in poor assemblability. There has also been a problem that a process for grinding both the surfaces of the mold after molding to expose the heat dissipation plate is required, resulting in an increase in manufacturing costs.

The present disclosure has been made to solve the above-described problem, and has its object to obtain a semiconductor device and an inverter unit enabling an improvement in assemblability and a reduction in manufacturing costs.

### Solution to Problem

A semiconductor device according to the present disclosure includes: a heat spreader; a semiconductor chip mounted on the heat spreader; a frame bonded to an upper surface of the semiconductor chip; mold resin sealing the heat spreader, the semiconductor chip and the frame and having a recess provided on an upper surface of the mold resin; and a heat dissipation plate externally attached to the recess via a thermally conductive material having thermal conductivity higher than that of the mold resin, wherein the heat dissipation plate is insulated from the semiconductor chip and the frame by the mold resin, and the heat dissipation plate is a flat plate having an upper surface and a lower surface which are opposite to each other and flat.

### Advantageous Effects of Invention

In the present disclosure, the heat dissipation plate is externally attached to the recess on the upper surface of the mold resin. Therefore, both the surfaces of the mold need not be ground after molding to expose the heat dissipation plate. The heat dissipation plate is externally attached, thereby making it possible to easily assemble a double-sided cooling structure. The heat dissipation plate can be produced easily and at low cost by grinding, punching press, or the like of a metal plate because it is a flat plate. Therefore, manufacturing costs can be reduced.

### BRIEF DESCRIPTION OF THE DRAWINGS

FIG. 1 is a cross-sectional view illustrating a semiconductor device according to an embodiment 1.

FIG. 2 is a top view illustrating the semiconductor device according to the embodiment 1.

FIG. 3 is a cross-sectional view illustrating the semiconductor device according to the embodiment 1 to which a heat dissipation plate is not externally attached.

FIG. 4 is a top view illustrating the semiconductor device according to the embodiment 1 to which a heat dissipation plate is not externally attached.

FIG. 5 is a cross-sectional view illustrating a state where a cooler is attached to the semiconductor device according to the embodiment 1.

FIG. 6 is a cross-sectional view illustrating a state where a cooler is attached to a semiconductor device according to a comparative example 1.

FIG. 7 is a cross-sectional view illustrating the vicinity of an upper surface of a semiconductor device according to an embodiment 2 in an enlarged manner.

FIG. 8 is a top view illustrating a semiconductor device according to an embodiment 3.

FIG. 9 is a top view illustrating a semiconductor device according to the embodiment 3 to which a heat dissipation plate is not externally attached.

FIG. 10 is a cross-sectional view illustrating a state before molding.

FIG. 11 is a cross-sectional view illustrating a state after molding.

FIG. 12 is a top view illustrating an inner portion of a semiconductor device according to an embodiment 4.

FIG. 13 is a side view illustrating an inverter unit according to an embodiment 5.

FIG. 14 is a cross-sectional view illustrating a semiconductor device according to the comparative example 2.

FIG. 15 is a side view illustrating an inverter unit according to the comparative example 2.

### DESCRIPTION OF EMBODIMENTS

A semiconductor device and an inverter unit according to the embodiments of the present disclosure will be described with reference to the drawings. The same components will be denoted by the same symbols, and the repeated description thereof may be omitted.

### Embodiment 1

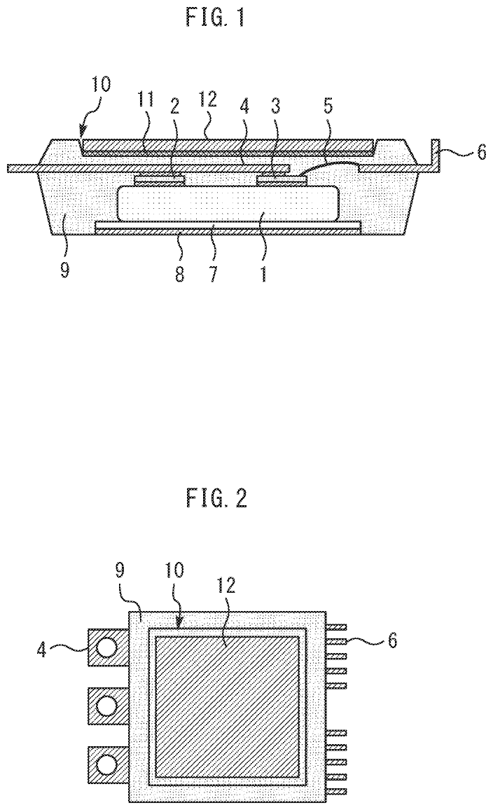

FIG. 1 is a cross-sectional view illustrating a semiconductor device according to an embodiment 1. FIG. 2 is a top view illustrating the semiconductor device according to the embodiment 1. The semiconductor device is a semiconductor device of a transfer mold type in which upper and lower heat dissipation surfaces are insulated from an internal configuration of the device.

Semiconductor chips 2 and 3 are mounted on a heat spreader 1. An example of the semiconductor chips 2 and 3 is an IGBT, a MOSFET, or a diode. A lower surface electrode of each of the semiconductor chips 2 and 3 is bonded to an upper surface of the heat spreader 1 with solder or the like. A frame 4 is bonded to an upper surface electrode of each of the semiconductor chips 2 and 3 with solder or the like. The frame 4 is a main electrode of the semiconductor device. A control electrode of the semiconductor chip 3 is connected to a frame 6 by a wire 5. The heat spreader 1 and the frames 4 and 6 are each a flat plate made of a metal such as copper.

An insulating sheet 7 is provided on a lower surface of the heat spreader 1. A metal foil 8 is provided on a lower surface of the insulating sheet 7. Mold resin 9 such as epoxy resin seals the heat spreader 1, the semiconductor chips 2 and 3, the frames 4 and 6, and the wire 5. Each of the frames 4 and 6 protrudes from a side surface of the mold resin 9. The metal foil 8 is exposed from a lower surface of the mold resin 9.

A recess 10 is provided on an upper surface of the mold resin 9. A heat dissipation plate 12 is externally attached to the recess 10 via a thermally conductive material 11. An example of the thermally conductive material 11 is grease, a graphite sheet, or an adhesive. The thermal conductivity of the thermally conductive material 11 is higher than the thermal conductivity (about 0.4 W/mK) of the mold resin 9 and is about 0.9 W/mK to 30 W/mK. Although a material for the heat dissipation plate 12 is a metal, the material is not limited to this, but may be ceramic or the like if a material having a higher thermal conductivity than that of the mold resin 9.

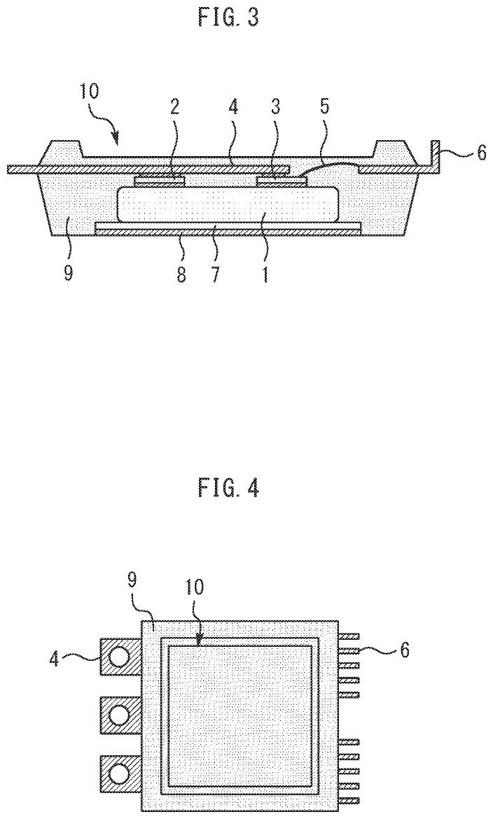

FIG. 3 is a cross-sectional view illustrating the semiconductor device according to the embodiment 1 to which a heat dissipation plate is not externally attached. FIG. 4 is a top view illustrating the semiconductor device according to the embodiment 1 to which a heat dissipation plate is not externally attached. In the recess 10, the frames 4 and 6 and the wire 5 are not exposed from the mold resin 9. Therefore, the heat dissipation plate 12 externally attached to the recess 10 is insulated from the semiconductor chips 2 and 3 and the frames 4 and 6 by the mold resin 9. The heat dissipation plate 12 is a flat plate made of a metal such as copper. An upper surface and a lower surface of the heat dissipation plate 12 are parallel to each other, and are each not irregular but flat. A cross section of the heat dissipation plate 12 is rectangular.

As described above, in the present embodiment, the heat dissipation plate 12 is externally attached to the recess 10 on the upper surface of the mold resin 9. Therefore, both the surfaces of the mold need not be ground after molding to expose the heat dissipation plate 12. The heat dissipation plate 12 is externally attached, thereby making it possible to easily assemble a double-sided cooling structure. The heat dissipation plate 12 can be produced easily and at low cost by grinding, punching press, or the like of a metal plate because it is a flat plate. Therefore, manufacturing costs can be reduced.

The heat dissipation plate 12 is insulated from the semiconductor chips 2 and 3 and the frames 4 and 6 by the mold resin 9. Therefore, when the device is incorporated into an inverter unit, an insulating plate need not be sandwiched between the heat dissipation plate 12 and an external heat sink. Therefore, assemblability can be improved.

The heat dissipation plate 12 is externally attached to the recess 10, whereby the heat dissipation plate 12 is easily positioned. The mold resin 9 above the frame 4 is preferably thinned within a range in which an insulating property can be ensured. This makes it possible to improve a heat dissipation property toward the upper surface side of the mold resin 9.

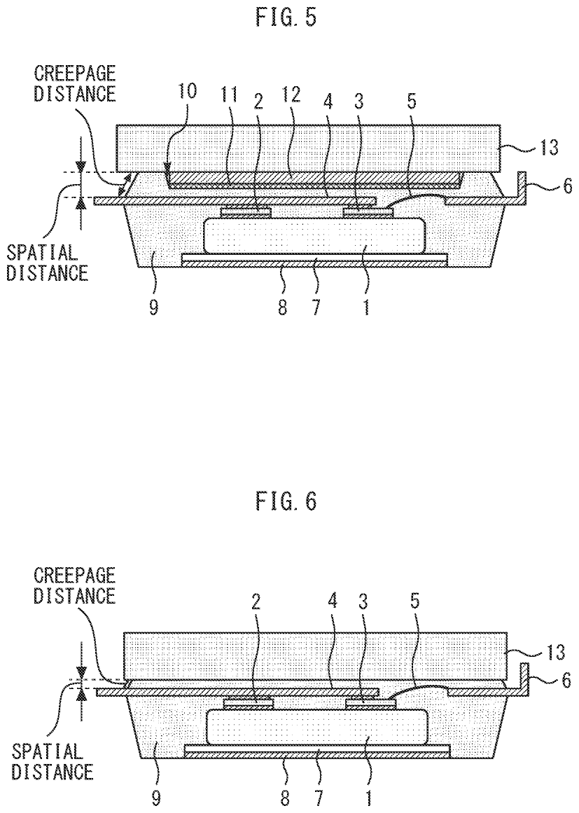

FIG. 5 is a cross-sectional view illustrating a state where a cooler is attached to the semiconductor device according to the embodiment 1. FIG. 6 is a cross-sectional view illustrating a state where a cooler is attached to a semiconductor device according to a comparative example 1. The comparative example 1 does not have a recess 10 and a heat dissipation plate 12, and an upper surface of mold resin 9 is flat. In the comparative example 1, when the mold resin 9 above a frame 4 is thinned, a creepage distance and a spatial distance between the frame 4 as a main electrode and a cooler 13 are shortened. On the other hand, in the present embodiment, the recess 10 is provided on the upper surface of the mold resin 9, and the heat dissipation plate 12 is externally attached thereto. Accordingly, a gap between the frame 4 and the heat dissipation plate 12 is narrowed without a creepage distance and a spatial distance being shortened, thereby making it possible to improve a heat dissipation property. That is, the double-sided cooling structure can be implemented without a creepage distance and a spatial distance between a main electrode and the cooler on the upper surface side of the mold resin 9 being changed.

The recess 10 is arranged immediately above the semiconductor chips 2 and 3, and the width of the recess 10 is larger than the width of each of the semiconductor chips 2 and 3. As a result, upward spread of heat from each of the semiconductor chips 2 and 3 can be effectively dispersed, thereby making it possible to improve a heat dissipation property. A plurality of recesses 10 may be arranged in a region immediately above the semiconductor chips 2 and 3.

The thickness of the mold resin 9 above the frame 4 is set depending on a withstand voltage of a material for the mold resin 9 and a dielectric withstand voltage of a product. The lower the dielectric withstand voltage of the product is, the smaller the thickness is made, thereby ensuring a heat dissipation property on the upper surface side. To ensure respective qualities of both the dielectric withstand voltage and the heat dissipation property, the thickness is preferably 0.2 mm to 1.0 mm.

An inner surface of the recess 10 is preferably changed into a mirror surface by mirror finishing. As a result, a thermal contact resistance between the mold resin 9 and the heat dissipation plate 12 can be suppressed, resulting in an improvement in a heat dissipation property.

### Embodiment 2

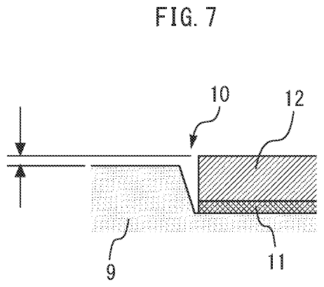

FIG. 7 is a cross-sectional view illustrating the vicinity of an upper surface of a semiconductor device according to an embodiment 2 in an enlarged manner. Although the upper surface of the heat dissipation plate 12 and the upper surface of the mold resin 9 are flush with each other in the embodiment 1, the height of an upper surface of a heat dissipation plate 12 is not less than the height of an upper surface of mold resin 9 in the present embodiment. As a result, the heat dissipation plate 12 protruding from the upper surface of the mold resin 9 reliably contacts a cooler 13, thereby making it possible to ensure a heat dissipation property.

A side surface of a recess 10 is tapered, and a side surface of the heat dissipation plate 12 is a vertical surface. A gap 14 occurs between the side surface of the recess 10 and the side surface of the heat dissipation plate 12 depending on a difference in angle therebetween. An excessive amount of a thermally conductive material 11 is accumulated in the gap 14. As a result, the thickness of the thermally conductive material 11 between a bottom surface of the recess 10 and a lower surface of the heat dissipation plate 12 can be made uniform, thereby making it possible to obtain a stable heat dissipation property. Even when the side surface of the recess 10 is a vertical surface, if the width of the recess 10 is larger than the width of the heat dissipation plate 12, the gap 14 occurs between both the side surfaces, thereby making it possible to obtain a similar effect.

### Embodiment 3

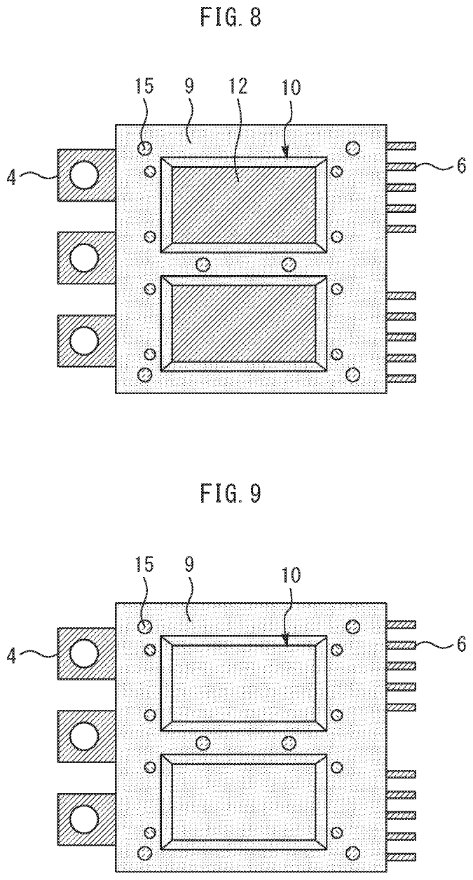

FIG. 8 is a top view illustrating a semiconductor device according to an embodiment 3. FIG. 9 is a top view illustrating a semiconductor device according to the embodiment 3 to which a heat dissipation plate is not externally attached. A plurality of recesses 10 and a plurality of heat dissipation plates 12 are arranged to avoid a trace 15 of an ejector pin or a movable pin on an upper surface of mold resin 9.

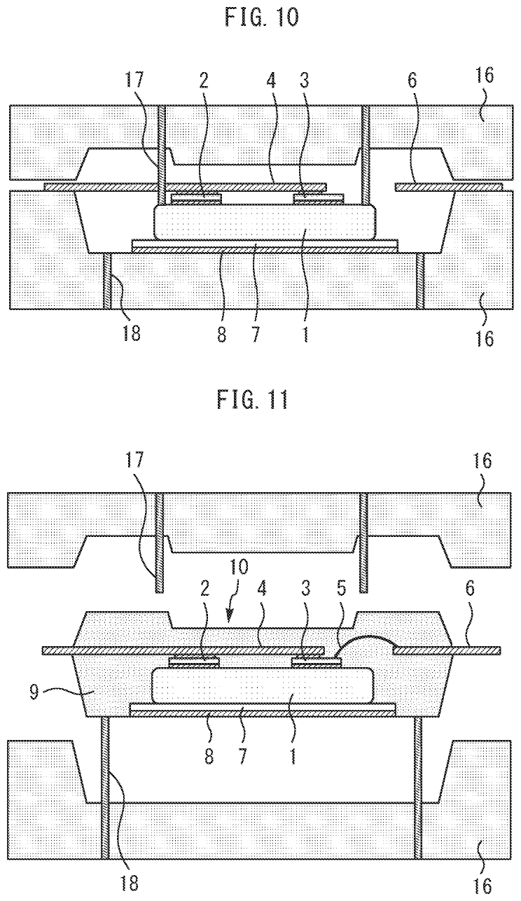

FIG. 10 is a cross-sectional view illustrating a state before molding FIG. 11 is a cross-sectional view illustrating a state after molding. As illustrated in FIG. 10, inner components such as a heat spreader 1 and semiconductor chips 2 and 3 are fixed by a movable pin 17 in a metal mold 16 before molding. Then, the mold resin 9 is injected into the metal mold 16, to perform molding. Then, as illustrated in FIG. 11, a molded semiconductor device protrudes from the metal mold 16 by an ejector pin 18. The trace 15 using the movable pin 17 or the ejector pin 18 remains on the upper surface of the mold resin 9.

In a region that does not interfere with the ejector pin 18 and the movable pin 17, the plurality of recesses 10 and the plurality of heat dissipation plates 12 can be arranged, as described above. An internal structure of the mold resin 9 is not different from a conventional one-sided cooling structure. Accordingly, production can be performed using the existing production facility.

### Embodiment 4

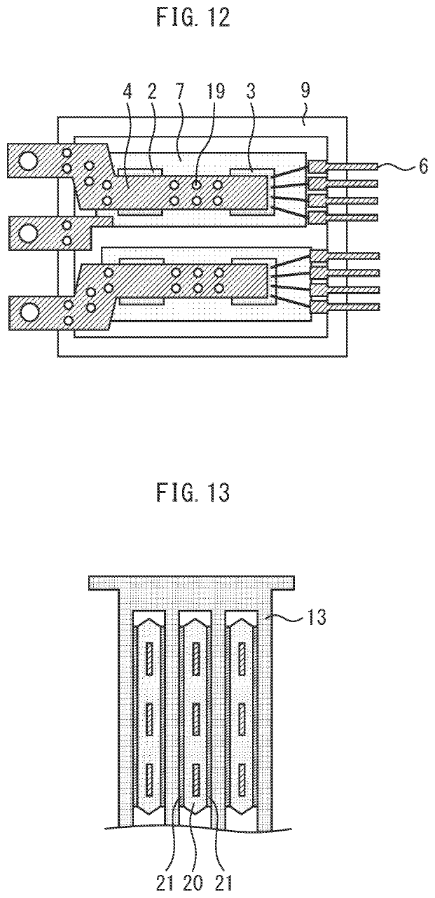

FIG. 12 is a top view illustrating an inner portion of a semiconductor device according to an embodiment 4. A frame 4 is provided with a plurality of holes 19. Mold resin 9 enters the plurality of holes 19. As a result, a narrow gap above the frame 4 can be filled with the mold resin 9. Adhesion between the mold resin 9 and the frame 4 can be improved using an anchor effect, resulting in an improvement in reliability.

The semiconductor chips 2,3 are not limited to a semiconductor chip formed of silicon, but instead may be formed of a wide-bandgap semiconductor having a bandgap wider than that of silicon. The wide-bandgap semiconductor is, for example, a silicon carbide, a gallium-nitride-based material, or diamond. A semiconductor chip formed of such a wide-bandgap semiconductor has a high voltage resistance and a high allowable current density, and thus can be miniaturized. The use of such a miniaturized semiconductor chip enables the miniaturization and high integration of the semiconductor device in which the semiconductor chip is incorporated. Further, since the semiconductor chip has a high heat resistance, a radiation fin of a heatsink can be miniaturized and a water-cooled part can be air-cooled, which leads to further miniaturization of the semiconductor device. Further, since the semiconductor chip has a low power loss and a high efficiency, a highly efficient semiconductor device can be achieved.

### Embodiment 5

FIG. 13 is a side view illustrating an inverter unit according to an embodiment 5. Each of a plurality of semiconductor devices 20 and a cooler 13 are stacked with grease 21 interposed therebetween. The cooler 13 is arranged on the upper surface side and the lower surface side of each of the semiconductor devices 20. The semiconductor device 20 is the semiconductor device having a double-sided cooling structure according to any one of the embodiments 1 to 4.

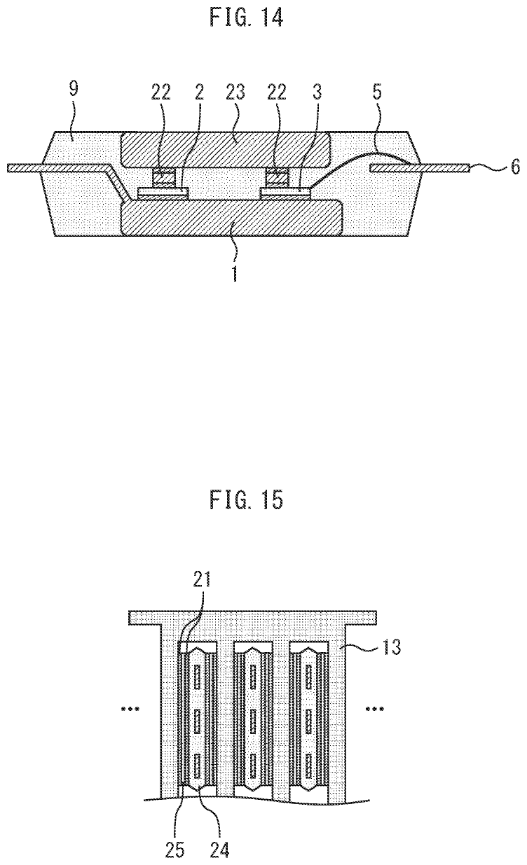

Then, an effect of the present embodiment will be described while being compared with that of a comparative example 2. FIG. 14 is a cross-sectional view illustrating a semiconductor device according to the comparative example 2. A metal plate 22 is bonded to an upper surface electrode of each of semiconductor chips 2 and 3 via solder or the like. A heat spreader 23 is bonded to an upper surface of the metal plate 22 via solder or the like. FIG. 15 is a side view illustrating an inverter unit according to the comparative example 2. A semiconductor device 24 is the semiconductor device illustrated in FIG. 14. In the comparative example 2, the heat spreader 23 is electrically connected to the semiconductor chips 2 and 3. Accordingly, an insulating substrate 25 such as a ceramic plate needs to be provided between the semiconductor device 24 and a cooler 13.

On the other hand, in the present embodiment, semiconductor chips 2 and 3 and a heat dissipation plate 12 are insulated from each other. Accordingly, an insulating substrate 25 need not be provided between the semiconductor device 20 and the cooler 13. Therefore, a heat spreader 1 and the heat dissipation plate 12 are thermally connected to the cooler 13 without via the insulating substrate 25. The insulating substrate 25 is not required, whereby the number of components can be reduced, resulting in improvements in assemblability and a heat dissipation property. The semiconductor device 20 according to the present embodiment can be replaced with a conventional semiconductor device having a double-sided cooling structure in the inverter unit.

### REFERENCE SIGNS LIST

1 heat spreader; 2,3 semiconductor chip; 4 frame; 9 mold resin; 10 recess; 11 thermally conductive material; 12 heat dissipation plate; 13 cooler; 15 trace; 17 movable pin; 18 ejector pin; 19 hole

1. A semiconductor device comprising:
a heat spreader;
a semiconductor chip mounted on the heat spreader;
a frame bonded to an upper surface of the semiconductor chip;
mold resin sealing the heat spreader, the semiconductor chip and the frame and having a recess provided on an upper surface of the mold resin; and
a heat dissipation plate externally attached to the recess via a thermally conductive material having thermal conductivity higher than that of the mold resin,
wherein the heat dissipation plate is insulated from the semiconductor chip and the frame by the mold resin, and
the heat dissipation plate is a flat plate having an upper surface and a lower surface which are opposite to each other and flat.

2. The semiconductor device according to claim 1, wherein an excessive amount of the thermally conductive material is accumulated in a gap between a side surface of the recess and a side surface of the heat dissipation plate.

3. The semiconductor device according to claim 2, wherein the side surface of the recess is tapered, and the side surface of the heat dissipation plate is a vertical surface.

4. The semiconductor device according to claim 1, wherein a height of an upper surface of the heat dissipation plate is not less than a height of the upper surface of the mold resin.

5. The semiconductor device according to claim 1, wherein a plurality of the recesses and a plurality of the heat dissipation plates are arranged to avoid a trace of an ejector pin or a movable pin on the upper surface of the mold resin.

6. The semiconductor device according to claim 1, wherein the frame is provided with a plurality of holes.

7. The semiconductor device according to claim 1, wherein the recess is arranged immediately above the semiconductor chip, and a width of the recess is larger than a width of the semiconductor chip.

8. The semiconductor device according to claim 1, wherein a thickness of the mold resin above the frame is 0.2 mm to 1.0 mm.

9. The semiconductor device according to claim 1, wherein an inner surface of the recess is a mirror surface.

10. The semiconductor device according to claim 1, wherein the semiconductor chip is made of a wide-band-gap semiconductor.

11. An inverter unit comprising:
the semiconductor device according to claim 1, and
a cooler arranged on an upper surface side and an lower surface side of the semiconductor device,
wherein the heat spreader and the heat dissipation plate are thermally connected to the cooler without via an insulating substrate.
